(19) United States
(12) Patent Application Publication
(10) Pub. No.: US 2026/0206232 A1
(43) Pub. Date: Jul. 16, 2026

(54) SEMICONDUCTOR MEMORY DEVICE

(71) Applicant: SAMSUNG ELECTRONICS CO., LTD., Suwon-si (KR)

(72) Inventors: Tan Young KIM, Suwon-si (KR); Jae Hyeok LEE, Suwon-si (KR); Ki Woong KIM, Suwon-si (KR); Ju Hyun KIM, Suwon-si (KR); Jun Ho JEONG, Suwon-si (KR)

(73) Assignee: SAMSUNG ELECTRONICS CO., LTD., Suwon-si (KR)

(21) Appl. No.: 19/423,537

(22) Filed: Dec. 17, 2025

(30) Foreign Application Priority Data
Jan. 15, 2025 (KR) 10-2025-0006106

(51) Int. Cl. H10B 61/00; H10N 50/10; H10N 50/85; H10N 50/01

(52) U.S. Cl. CPC H10B 61/10; H10B 61/22; H10N 50/10; H10N 50/85; H10N 50/01

(57) ABSTRACT

A magnetic memory device includes a pinned layer pattern, a free layer pattern on the pinned layer pattern, a tunnel barrier layer pattern between the pinned layer pattern and the free layer pattern, and an oxide layer pattern which is spaced apart from the tunnel barrier layer pattern with the free layer pattern interposed therebetween, and includes tantalum (Ta) oxide, in which the free layer pattern includes a first sub-free layer and a second sub-free layer which are stacked in sequence, a thickness of the second sub-free layer is smaller than that of the first sub-free layer, and the second sub-free layer includes a material having a higher boron affinity than the first sub-free layer.

### CROSS-REFERENCE TO RELATED APPLICATION

This application claims priority from Korean Patent Application No. 10-2025-0006106 filed on January 15, 2025 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a magnetic memory device.

### 2. Description of the Related Art

As electronic devices become faster and attain a lower power consumption, memory devices built into them also require rapid read/write operations and low operating voltages. Magnetic memory devices are being researched as memory devices that satisfy such requirements. The magnetic memory devices are non-volatile, capable of operating at a high speed, and are attracting attention as next-generation memories.

Meanwhile, as magnetic memory elements gradually become highly integrated, STT-MRAM, which stores information by the use of a spin transfer torque (STT) phenomenon is being researched. The STT-MRAM may store information by directly applying a current to a magnetic tunnel junction element to induce magnetization reversal. The highly integrated STT-MRAM requires a high-speed operation and a low current operation.

### SUMMARY

Aspects of the present disclosure provide a magnetic memory device having improved performance and reliability.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

A magnetic memory device according to some embodiments of the present disclosure includes a pinned layer pattern, a free layer pattern on the pinned layer pattern, a tunnel barrier layer pattern between the pinned layer pattern and the free layer pattern, and an oxide layer pattern which is spaced apart from the tunnel barrier layer pattern with the free layer pattern interposed therebetween, and includes tantalum (Ta) oxide, in which the free layer pattern includes a first sub-free layer and a second sub-free layer which are stacked in sequence, a thickness of the second sub-free layer is smaller than that of the first sub-free layer, and the second sub-free layer includes a material having a higher boron affinity than the first sub-free layer.

A magnetic memory device according to some other embodiments of the present disclosure includes a pinned layer pattern, a free layer pattern on the pinned layer pattern, a tunnel barrier layer pattern between the pinned layer pattern and the free layer pattern, an oxide layer pattern which is spaced apart from the tunnel barrier layer pattern with the free layer pattern interposed therebetween, and includes a metal oxide, and a capping layer pattern which is spaced apart from the free layer pattern with the oxide layer pattern interposed therebetween, in which the free layer pattern includes a first sub-free layer and a second sub-free layer that include different metal materials from each other and are sequentially stacked, and an insertion layer between the first and second sub-free layers, a thickness of the insertion layer is smaller than a thickness of the first sub-free layer, the first sub-free layer includes cobalt iron boride (CoFeB), the second sub-free layer is free of cobalt (Co), and the insertion layer includes a material having a greater boron affinity than the first sub-free layer.

A magnetic memory device according to some other embodiments of the present disclosure includes a lower electrode on a substrate, an upper electrode on the lower electrode, and a magnetic tunnel junction element between the lower electrode and the upper electrode, wherein the magnetic tunnel junction element includes a seed layer on the lower electrode, a pinned layer pattern on the seed layer, a free layer pattern on the pinned layer pattern, a tunnel barrier layer pattern between the pinned layer pattern and the free layer pattern, an oxide layer pattern which is spaced apart from the tunnel barrier layer pattern with the free layer pattern interposed therebetween, and includes tantalum (Ta) oxide, and a capping layer pattern which is spaced apart from the free layer pattern with the oxide layer pattern interposed therebetween, and wherein the free layer pattern includes a first sub-free layer and a second sub-free layer stacked in sequence, and an insertion layer between the first and second sub-free layers, the first sub-free layer includes at least one of cobalt (Co) or iron (Fe), the second sub-free layer includes iron (Fe) and is free of cobalt (Co), the insertion layer includes at least one of molybdenum (Mo), vanadium (V), tungsten (W), aluminum (Al) or titanium (Ti), and a thickness of the insertion layer is smaller than a thickness of the second sub-free layer.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exemplary block diagram of a magnetic memory device according to some embodiments;

FIG. 2 is an exemplary circuit diagram for explaining a cell array of a magnetic memory device according to some embodiments;

FIG. 3 is a schematic diagram for explaining a magnetic tunnel junction element of the magnetic memory device according to some embodiments;

FIG. 4 is a graph showing a perpendicular magnetic anisotropy depending on annealing temperature;

FIG. 5 is a graph showing a coefficient of variation CV of a switching current ISW of the magnetic tunnel junction element;

FIG. 6 is a graph for explaining a thickness of an insertion layer of the magnetic memory device according to some embodiments;

FIGS. 7, 8 and 9 are schematic diagrams for explaining a magnetic tunnel junction element of a magnetic memory device according to some embodiments;

FIG. 10 is an exemplary plan view of a magnetic memory device according to some embodiments;

FIG. 11 is a cross-sectional view taken along a line I-I’ of FIG. 10;

FIGS. 12, 13, 14, 15 and 16 are intermediate step diagrams for describing the method for fabricating the magnetic memory device according to some embodiments.

### DETAILED DESCRIPTION OF THE EMBODIMENTS

Hereinafter, embodiments according to the technical idea of the present disclosure will be described referring to the accompanying drawings.

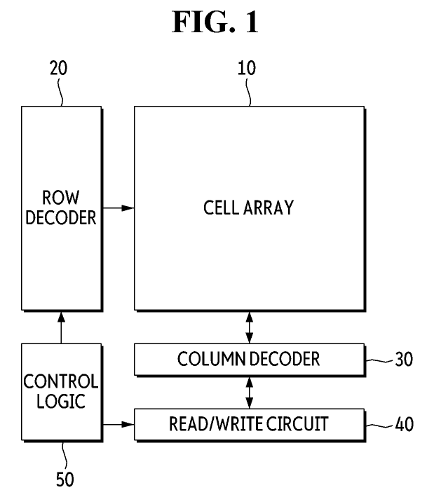

FIG. 1 is an exemplary block diagram of a magnetic memory device according to some embodiments.

Referring to FIG. 1, the magnetic memory device according to some embodiments includes a cell array 10, a row decoder 20, a column decoder 30, a read/write circuit 40, and a control logic 50.

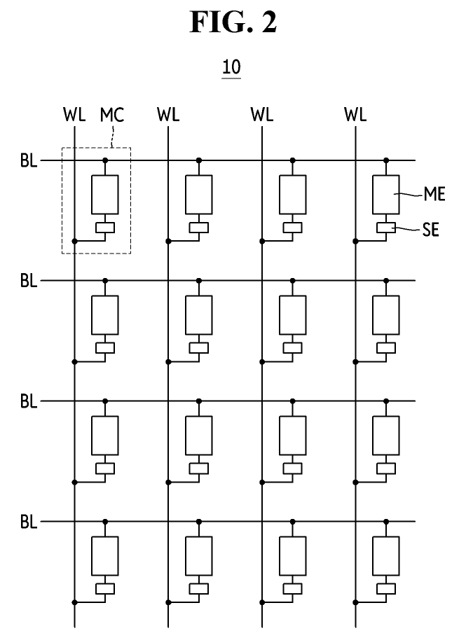

The cell array 10 may include a plurality of word lines and a plurality of bit lines. Memory cells may be connected to points at which the word lines and the bit lines intersect each other. The cell array 10 will be described in more detail below in the description of FIG. 2.

The row decoder 20 may be connected to the cell array 10 through the word lines. The row decoder 20 may decode an address that is input from the outside to select one of a plurality of word lines.

The column decoder 30 may be connected to the cell array 10 through the bit lines. The column decoder 30 may decode an address that is input from the outside to select one of a plurality of bit lines. The bit line selected by the column decoder 30 may be connected to the read/write circuit 40.

The read/write circuit 40 may provide a bit line bias for accessing a selected memory cell in accordance with the control of the control logic 50. For example, the read/write circuit 40 may provide a bit line bias to the selected bit line to write or read the input data to the memory cell.

The control logic 50 may output control signals for controlling the magnetic memory device in accordance with a command signal provided from the outside. The control signals that are output from the control logic 50 may control the read/write circuit 40.

FIG. 2 is an exemplary circuit diagram for explaining a cell array of a magnetic memory device according to some embodiments.

Referring to FIG. 2, the cell array 10 includes a plurality of bit lines BL, a plurality of word lines WL, and a plurality of unit memory cells MC.

The word lines WL may extend in a first direction. The bit lines BL may extend in a second direction intersecting the first direction, and intersect the word lines WL.

The unit memory cells MC may be arranged two-dimensionally or three-dimensionally. Each unit memory cell MC may be connected to intersections between the word lines WL and the bit lines BL that intersect each other. Thus, each unit memory cell MC connected to the word lines WL may be connected to a read/write circuit (e.g., 40 of FIG. 1) by the bit line BL. Each unit memory cell MC may include a magnetic tunnel junction element ME and a selection element SE.

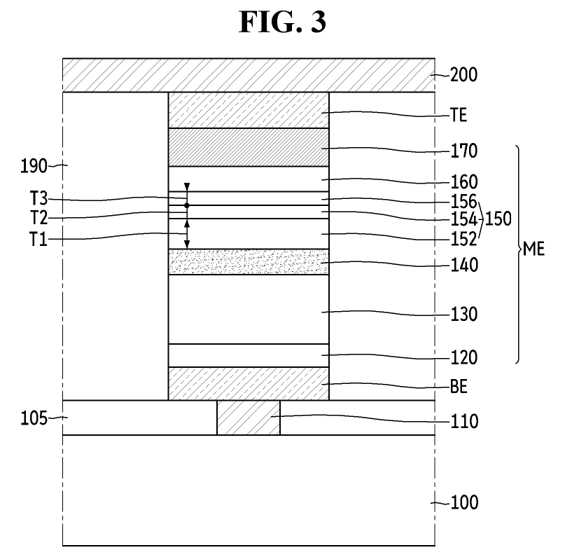

The magnetic tunnel junction element ME may be connected between the bit line BL and the selection element SE, and the selection element SE may be connected between the magnetic tunnel junction element ME and the word line WL. The magnetic tunnel junction element ME may include a pinned layer, a free layer, and a tunnel barrier layer. The magnetic tunnel junction element ME will be described below in more detail in the description of FIG. 3.

The selection element SE may be configured to selectively control the flow of charge that passes through the magnetic tunnel junction element ME. For example, the selection element SE may include at least one of a diode, a PNP bipolar transistor, an NPN bipolar transistor, an NMOS field effect transistor, or a PMOS field effect transistor. When the selection element SE is configured as a bipolar transistor or a MOS field effect transistor, which is a three-terminal element, an additional wiring (e.g., a source line) may be connected to the selection element SE.

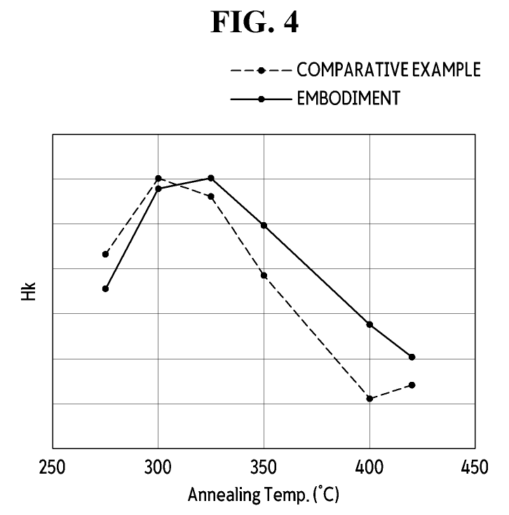

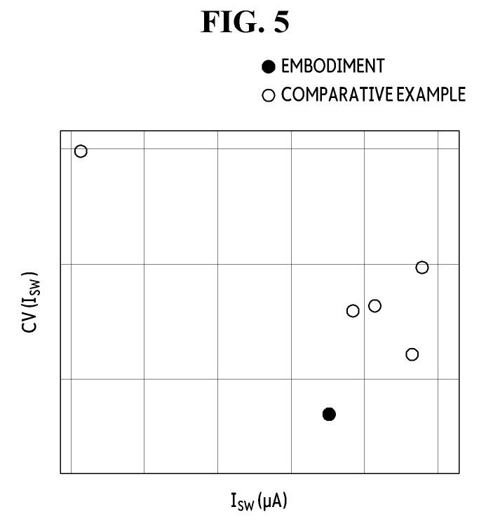

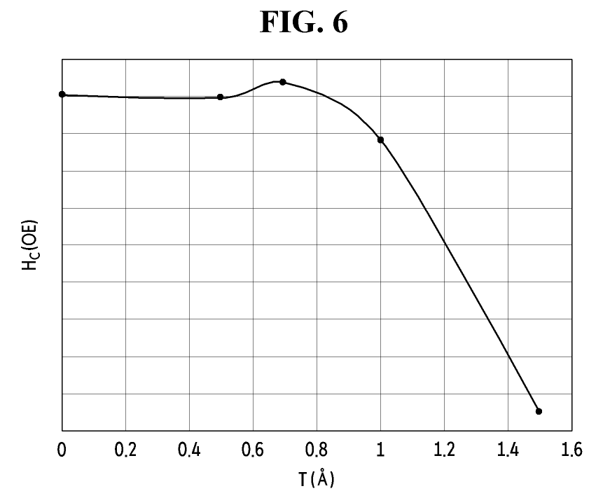

FIG. 3 is a schematic diagram for explaining a magnetic tunnel junction element of the magnetic memory device according to some embodiments. FIG. 4 is a graph showing a perpendicular magnetic anisotropy depending on annealing temperature. FIG. 5 is a graph showing a coefficient of variation CV of a switching current I_{SW} of the magnetic tunnel junction element. FIG. 6 is a graph for explaining a thickness of an insertion layer of the magnetic memory device according to some embodiments.

Referring to FIG. 3, the magnetic tunnel junction element ME of the magnetic memory device according to some embodiments may include a pinned layer pattern 130, a tunnel barrier layer pattern 140, a free layer pattern 150, an oxide layer pattern 160, and a capping layer pattern 170.

The pinned layer pattern 130 may have a fixed magnetization direction. For example, the magnetization direction of the pinned layer pattern 130 may be fixed regardless of a program current passing through it.

The pinned layer pattern 130 may include a ferromagnetic material. For example, the pinned layer pattern 130 may include, but is not limited to, at least one of an amorphous rare earth element alloy; a multi-layer thin film in which a ferromagnetic metal (FM) and a nonmagnetic metal (NM) are alternately stacked; an alloy having an L1₀ type crystal structure; a cobalt-based alloy; or combinations thereof.

The amorphous rare earth element alloy may include, for example, alloys such as TbFe, TbCo, TbFeCo, DyTbFeCo, and GdTbCo. The multi-layer thin film in which the ferromagnetic metal and the non-magnetic metal are alternately stacked may include, for example, multi-layer thin films such as Co/Pt, Co/Pd, CoCr/Pt, Co/Ru, Co/Os, Co/Au, and Ni/Cu. The alloy having the L1₀ type crystal structure may include, for example, alloys such as Fe₅₀Pt₅₀, Fe₅₀Pd₅₀, Co₅₀Pt₅₀, Fe₃₀Ni₂₀Pt₅₀, and Co₃₀Ni₂₀Pt₅₀. The cobalt-based alloy may include, for example, alloys such as CoCr, CoPt, CoCrPt, CoCrTa, CoCrPtTa, CoCrNb, and CoFeB. As an example, the pinned layer pattern 130 may include a CoFeB film.

In some embodiments, the pinned layer pattern 130 may have perpendicular magnetic anisotropy (PMA). That is, the pinned layer pattern 130 may have a magnetization easy axis in a direction perpendicular to an extending direction of the pinned layer pattern 130 (or a thickness direction of the pinned layer pattern 130). For example, the magnetization direction of the pinned layer pattern 130 may be fixed perpendicularly.

The free layer pattern 150 may have variable magnetization directions. For example, the magnetization direction of the free layer pattern 150 may be variable depending on the program current passing through it. In some embodiments, the magnetization direction of the free layer pattern 150 may change by a spin transfer torque (STT).

The free layer pattern 150 may include at least one magnetic element. The magnetic element of the free layer pattern 150 may include, for example, but is not limited to, at least one of cobalt (Co), iron (Fe) or nickel (Ni).

In some embodiments, the free layer pattern 150 may include at least one magnetic element and boron (B). For example, the free layer pattern 150 may include at least one of cobalt (Co), iron (Fe) and nickel (Ni), or boron (B).

In some embodiments, the free layer pattern 150 may have a perpendicular magnetic anisotropy (PMA). That is, the free layer pattern 150 may have an easy magnetization axis in a direction perpendicular to the extending direction of the free layer pattern 150 (or the thickness direction of the free layer pattern 150). For example, the magnetization direction of the free layer pattern 150 may be magnetized to be parallel or antiparallel to the magnetization direction of the pinned layer pattern 130.

In some embodiments, the free layer pattern 150 may include magnetic elements that may be coupled with oxygen atoms to induce an interfacial perpendicular magnetic anisotropy (i-PMA). The magnetic element may be, for example, iron (Fe). As an example, the free layer pattern 150 may include a CoFeB film or a CoFe film.

In some embodiments, the free layer pattern 150 may be amorphous. As an example, the free layer pattern 150 may include an amorphous CoFeB film or an amorphous CoFe film.

A specific structure of magnetization easy axis will be described below.

The tunnel barrier layer pattern 140 may be interposed between the pinned layer pattern 130 and the free layer pattern 150. The tunnel barrier layer pattern 140 may be provided as an insulated tunnel barrier that generates quantum mechanical tunneling between the pinned layer pattern 130 and the free layer pattern 150.

The tunnel barrier layer pattern 140 may include, for example, but is not limited to, at least one of magnesium oxide (MgO), aluminum oxide (Al₂O₃), silicon oxide (SiO₂), tantalum oxide (Ta₂O₅), silicon nitride (SiN), aluminum nitride (AlN), or combinations thereof. As an example, the tunnel barrier layer pattern 140 may include a magnesium oxide film (MgO film) having a face-centered cubic (FCC) crystal structure or a sodium chloride (NaCl) crystal structure.

The magnetic tunnel junction element, which includes the pinned layer pattern 130, the tunnel barrier layer pattern 140 and the free layer pattern 150, may function as a variable resistance element that may switch between two resistance states by an electrical signal (e.g., program current) applied thereto. For example, when the magnetization direction of the pinned layer pattern 130 and the magnetization direction of the free layer pattern 150 are parallel to each other, the magnetic tunnel junction element has a low resistance value, which may be stored as data “0”. In contrast, when the magnetization direction of the pinned layer pattern 130 and the magnetization direction of the free layer pattern 150 are antiparallel to each other, the magnetic tunnel junction element has a high resistance value, which may be stored as data “1”.

In some embodiments, the pinned layer pattern 130, the tunnel barrier layer pattern 140, and the free layer pattern 150 may be sequentially stacked on the substrate 100. The substrate 100 may be, for example, but is not limited to, a silicon substrate, a gallium arsenide substrate, a silicon germanium substrate, a ceramic substrate, a quartz substrate or a display glass substrate, or may be an SOI (Semiconductor On Insulator) substrate.

The oxide layer pattern 160 may be spaced apart from the tunnel barrier layer pattern 140 with the free layer pattern 150 interposed therebetween. For example, the oxide layer pattern 160 may be stacked on an upper side of the free layer pattern 150. In some embodiments, the oxide layer pattern 160 may be in contact with the free layer pattern 150.

The oxide layer pattern 160 may include a metal oxide. For example, the oxide layer pattern 160 may include tantalum (Ta), magnesium (Mg), iron (Fe), cobalt (Co), tungsten (W), iridium (Ir), ruthenium (Ru), molybdenum (Mo), hafnium (Hf), zirconium (Zr), niobium (Nb), aluminum (Al), manganese (Mn), and alloys thereof. Although the oxide layer pattern 160 is only shown as being a single film in FIG. 3, this is only an example, and the oxide layer pattern 160 may include multiple films including different metal oxides from each other.

The oxide layer pattern 160 may induce the magnetic anisotropy at the interface with the free layer pattern 150 to improve the magnetic anisotropy of the free layer pattern 150. For example, oxygen atoms supplied from the oxide layer pattern 160 induce interfacial perpendicular magnetic anisotropy (i-PMA) at the interface with the free layer pattern 150, and may improve the perpendicular magnetic anisotropy (PMA) of the free layer pattern 150.

When the free layer pattern 150 includes boron (B), the oxide layer pattern 160 may further include boron (B). For example, the oxide layer pattern 160 may include metal borate. The metal borate may include, for example, at least one of TaBO, MgBO, FeBO, CoBO, CoFeBO, IrBO, RuBO, MoBO, HfBO, ZrBO or NbO. As an example, the oxide layer pattern 160 may include a TaBO film.

When the free layer pattern 150 does not include boron (B), the oxide layer pattern 160 may also not include boron (B). For example, the oxide layer pattern 160 may include at least one of TaO, MgO, WO, IrO, RuO, MoO, HfO or ZrO. As an example, the oxide layer pattern 160 may include a TaO film.

The capping layer pattern 170 may be spaced apart from the free layer pattern 150 with the oxide layer pattern 160 interposed therebetween. For example, the capping layer pattern 170 may be stacked on the upper side of the oxide layer pattern 160. In some embodiments, the capping layer pattern 170 may be in contact with the oxide layer pattern 160.

The capping layer pattern 170 may include a metal or a metal nitride. The metal may include, for example, but is not limited to, at least one of tantalum (Ta), magnesium (Mg), tungsten (W), iridium (Ir), ruthenium (Ru), molybdenum (Mo), hafnium (Hf) or zirconium (Zr). The metal nitride may include, for example, but is not limited to, at least one of titanium nitride (TiN), tantalum nitride (TaN), aluminum nitride (AlN), zirconium nitride (ZrN), niobium nitride (NbN), molybdenum nitride (MoN), or combinations thereof. The capping layer pattern 170 may protect the magnetic tunnel junction element ME in a subsequent process after the capping layer pattern 170 is formed.

When the free layer pattern 150 includes boron (B), the capping layer pattern 170 may further include boron (B). For example, the capping layer pattern 170 may include metal boride. The metal boride may include, for example, at least one of TaB, MgB, CoFeB, IrB, RuB, MoB, HfB or ZrB. As an example, the capping layer pattern 170 may include a TaB film.

When the free layer pattern 150 does not include boron (B), the capping layer pattern 170 may also not include boron (B). For example, the capping layer pattern 170 may include at least one of tantalum (Ta), magnesium (Mg), tungsten (W), iridium (Ir), ruthenium (Ru), molybdenum (Mo), hafnium (Hf) or zirconium (Zr). As an example, the capping layer pattern 170 may include a Ta film.

In some embodiments, the magnetic tunnel junction element ME may further include a seed layer pattern 120. The pinned layer pattern 130 may be stacked on the upper side of the seed layer pattern 120. The seed layer pattern 120 may be provided as a seed layer of the pinned layer pattern 130. For example, when the pinned layer pattern 130 is formed of a material having an L1₀ crystal structure, the seed layer pattern 120 may include conductive metal nitrides (e.g., titanium nitride, tantalum nitride, chromium nitride or vanadium nitride) having a face-centered cubic crystal structure (FCC crystal structure or sodium chloride (NaCl) crystal structure). Alternatively, for example, when the pinned layer pattern 130 has a dense hexagonal crystal structure, the seed layer pattern 120 may include a conductive material (e.g., ruthenium) having a dense hexagonal crystal structure.

In some embodiments, the seed layer pattern 120 may include at least one of tantalum (Ta), ruthenium (Ru), titanium (Ti), palladium (Pd), platinum (Pt), magnesium (Mg), aluminum (Al) or nitrides thereof. In some embodiments, the seed layer pattern 120 may be made up of multi-layered thin films in which different non-magnetic metals are stacked. For example, the seed layer pattern 120 may include a first non-magnetic seed layer and a second non-magnetic seed layer that are stacked sequentially. The first non-magnetic seed layer may include tantalum (Ta), and the second non-magnetic seed layer may include platinum (Pt), but the embodiment is not limited thereto.

The magnetic tunnel junction element ME may be connected to the selection element (e.g., SE of FIG. 2) on the substrate 100. For example, a first interlayer insulating film 105, a contact plug 110 and a lower electrode pattern BE may be formed on the substrate 100.

The first interlayer insulating film 105 may cover the upper side of the substrate 100. The first interlayer insulating film 105 may include, for example, but is not limited to, silicon oxide, silicon oxynitride, or the like.

The contact plug 110 penetrates the first interlayer insulating film 105, and may be connected to the selection element (e.g., SE of FIG. 2) on the substrate 100. The contact plug 110 may include a conductive material, for example, but is not limited to, at least one of a doped semiconductor material (e.g., doped silicon), a metal (e.g., tungsten, aluminum, copper, titanium, and/or tantalum), a conductive metal nitride (e.g., titanium nitride, tantalum nitride and/or tungsten nitride) or a metal-semiconductor compound (e.g., metal silicide).

A lower electrode pattern BE may be formed on the first interlayer insulating film 105 and the contact plug 110. The lower electrode pattern BE may be electrically connected to the contact plug 110. The magnetic tunnel junction element ME may be formed on the lower electrode pattern BE. For example, the lower electrode pattern BE may be interposed between the contact plug 110 and the magnetic tunnel junction element ME. Accordingly, the magnetic tunnel junction element ME may be electrically connected to the selection element (e.g., SE of FIG. 2) on the substrate 100. The lower electrode pattern BE may include, for example, but is not limited to, a conductive metal (e.g., titanium or tantalum) or a conductive metal nitride (e.g., titanium nitride or tantalum nitride).

The magnetic tunnel junction element ME may be connected to a conductive line 200 on the magnetic tunnel junction element ME. For example, the upper electrode pattern TE, the second interlayer insulating film 190, and the conductive line 200 may be formed on the magnetic tunnel junction element ME.

An upper electrode pattern TE may be formed on the magnetic tunnel junction element ME. For example, the upper electrode pattern TE may be stacked on an upper side of the capping layer pattern 170. The upper electrode pattern TE may include, for example, but is not limited to, a conductive metal or a conductive metal nitride. For example, the upper electrode pattern TE may include at least one of ruthenium (Ru), tantalum (Ta), or nitrides thereof.

A second interlayer insulating film 190 may be formed on the first interlayer insulating film 105. The second interlayer insulating film 190 may cover the first interlayer insulating film 105, the lower electrode pattern BE, the magnetic tunnel junction element ME, and the upper electrode pattern TE. The second interlayer insulating film 190 may include, for example, but is not limited to, silicon oxide, silicon oxynitride or the like.

The conductive line 200 may be formed on the second interlayer insulating film 190 and the upper electrode pattern TE. The conductive line 200 may be electrically connected to the upper electrode pattern TE. For example, the upper electrode pattern TE may be interposed between the magnetic tunnel junction element ME and the conductive line 200. Accordingly, the magnetic tunnel junction element ME may be electrically connected to the conductive line 200. In some embodiments, conductive line 200 may be provided as a bit line BL of FIG. 2.

The free layer pattern 150 may include a first sub-free layer 152 and a second sub-free layer 156 that are sequentially stacked, and an insertion layer 154 between the first and second sub-free layers 152 and 156. In another embodiment, the first sub-free layer 152, the insertion layer 154, and the second sub-free layer 156 may be called a first sub-free layer, a second sub-free layer, and a third sub-free layer, respectively, stacked in sequence.

The first sub-free layer 152 may include at least one of cobalt (Co) or iron (Fe). When the first sub-free layer 152 includes boron (B), the first sub-free layer 152 may include cobalt iron boride (CoFeB).

The insertion layer 154 may include a material having a higher boron affinity than the first sub-free layer 152. For example, the insertion layer 154 may include at least one of molybdenum (Mo), vanadium (V), tungsten (W), aluminum (Al) or titanium (Ti), and the first sub-free layer 152 may include at least one of cobalt (Co) or iron (Fe). When the insertion layer 154 includes boron (B), the insertion layer 154 may include a compound of at least one of molybdenum (Mo), vanadium (V), tungsten (W), aluminum (Al) or titanium (Ti) with boron (B).

As an example, the insertion layer 154 may include a material having a lower boron affinity than the oxide layer pattern 160. For example, in this case, the insertion layer 154 may include molybdenum (Mo), and the oxide layer pattern 160 may include tantalum (Ta).

As another example, the insertion layer 154 may include a material having a higher boron affinity than the oxide layer pattern 160. As an example, in this case, the insertion layer 154 may include at least one of vanadium (V) or tungsten (W), and the oxide layer pattern 160 may include tantalum (Ta).

The second sub-free layer 156 may include magnetic elements that may be coupled with oxygen atoms to induce interfacial perpendicular magnetic anisotropy (i-PMA). The magnetic elements may be, for example, iron (Fe). For example, the second sub-free layer 156 includes iron (Fe), but may not include cobalt (Co). When the second sub-free layer 156 includes boron (B), the second sub-free layer 156 may include iron boride (FeB).

For example, a thickness T2 of the insertion layer 154 may be smaller than the thickness T1 of the first sub-free layer 152. A thickness T3 of the second sub-free layer 156 may be smaller than the thickness T1 of the first sub-free layer 152. The thickness T2 of the insertion layer 154 may be, but is not limited to, equal to or less than the thickness T3 of the second sub-free layer 156.

An amorphous magnetic material containing boron (B) may be used as the free layer of the magnetic tunnel junction element. However, in a high-temperature process for fabricating a magnetic memory device including the magnetic tunnel junction element, there is a problem that boron atoms contained in the free layer spread into adjacent layers, and deteriorate the characteristics of the magnetic memory device. For example, in a high-temperature process such as a heat treatment process and/or a post-process (or Back End of Line; BEOL), boron atoms of the free layer may spread toward an oxide layer and/or a capping layer stacked on the free layer. Accordingly, the amorphous magnetic material of the free layer may change to a crystalline material, or excess oxygen of the oxide layer may flow into the free layer from which boron leaves, thereby deteriorating the dispersion of the magnetic memory device.

However, in the magnetic memory device according to some embodiments, since the magnetic tunnel junction element ME includes the insertion layer 154 between the first and second sub-free layers 152 and 156, it is possible to prevent the boron atoms contained in the free layer pattern 150 from spreading. For example, the insertion layer 154 may include a material having a higher boron affinity than the first sub-free layer 152, and may include a material having a lower boron affinity than the oxide layer pattern 160. By slowing down the crystallization rate of the free layer pattern 150 in a high-temperature process through the insertion layer 154, it is possible to minimize the inflow of excessive oxygen into the free layer pattern 150. As a result, it is possible to provide a magnetic memory device in which the distribution of switching current is improved, and reliability and performance are enhanced.

Hereinafter, effects of the magnetic memory device according to some embodiments will be described referring to the embodiment, comparative example, and FIGS. 4 to 6.

### Embodiment

A magnetic tunnel junction element including the insertion layer 154 containing molybdenum (Mo) was fabricated in the free layer pattern 150.

### Comparative Example

The magnetic tunnel junction element was fabricated in manner similar to the above embodiment, except that the insertion layer 154 contains molybdenum (Mo).

Next, the annealing temperature is changed, and the perpendicular magnetic anisotropy (Hk) of the magnetic tunnel junction elements according to the embodiment and the comparative example is measured and normalized, and is shown in FIG. 4. For reference, a vertical axis of FIG. 4 may represent values obtained by measuring the perpendicular magnetic anisotropy (Hk) and then normalizing the same.

Referring to FIG. 4, it may be seen that the magnetic tunnel junction element according to the comparative example, in which the insertion layer 154 does not contain molybdenum (Mo), exhibits a maximum perpendicular magnetic anisotropy at a temperature of about 300°C, and on the other hand, the magnetic tunnel junction element according to the embodiment exhibits a maximum perpendicular magnetic anisotropy at a relatively high annealing temperature (about 300°C to 350°C). That is, it may be seen that the magnetic tunnel junction element of the embodiment maintains perpendicular magnetic anisotropy at a higher temperature than the magnetic tunnel junction element of the comparative example. In other words, the magnetic tunnel junction element of the embodiment may minimize the deterioration caused by oxygen inflow into the free layer, compared to the magnetic tunnel junction element of the comparative example.

Next, the switching current I_{SW} of the magnetic tunnel junction elements according to the embodiment and the comparative example is measured and is shown in FIG. 5. Specifically, FIG. 5 is a graph showing the coefficient of variation (CV) of the switching current I_{SW}.

Referring to FIG. 5, it may be seen that the magnetic tunnel junction element according to the embodiment exhibits a relatively low coefficient of variation (CV). As a result, it may be seen that the magnetic tunnel junction element according to the embodiment exhibits an improved switching current dispersion compared to the comparative example.

Referring to FIG. 6, it may be seen that the coercivity (Hc) according to the thickness T of the insertion layer 154. For example, the thickness (T2 of FIG. 3) of the insertion layer 154 of the magnetic tunnel junction element according to the embodiment may be greater than 0 angstrom and smaller than 1.5 angstroms. Preferably, the thickness (T2 of FIG. 3) of the insertion layer 154 of the magnetic tunnel junction element may be greater than 0 angstrom and smaller than 1 angstrom.

Referring to FIG. 6, it may be seen that when the thickness of the insertion layer 154 is equal to or greater than 1 angstrom, the coercivity (Hc) of the magnetic memory device rapidly decreases. That is, when the thickness of the insertion layer 154 is less than 1 angstrom, the thermal stability and the data storage characteristics and write characteristics of the magnetic memory device may be appropriately adjusted.

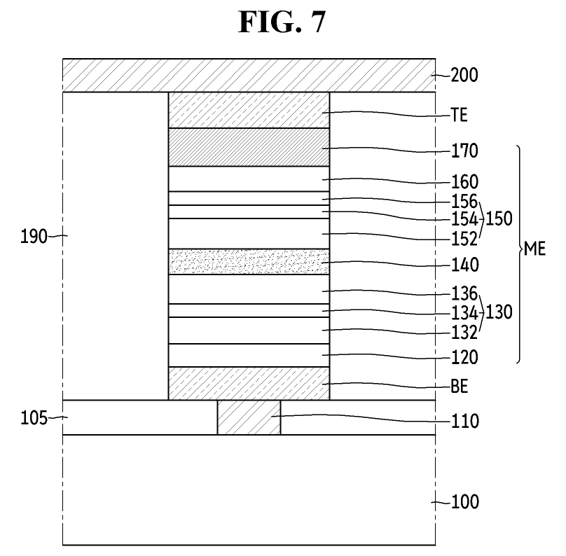

FIGS. 7 through 9 are schematic diagrams for explaining a magnetic tunnel junction element of a magnetic memory device according to some embodiments. For convenience of explanation, repeated parts of contents explained above using FIGS. 1 through 6 will be briefly explained or omitted.

Referring to FIG. 7, in the magnetic memory device according to some embodiments, the pinned layer pattern 130 may include a synthetic anti-ferromagnet (SAF).

For example, the pinned layer pattern 130 may include a first sub-pinned layer 132, an anti-ferromagnetic coupling layer 134, and a second sub-pinned layer 136 that are sequentially stacked on the seed layer pattern 120. The pinned layer pattern 130 may exhibit, for example, anti-ferromagnetic coupling (AFC) characteristics due to RKKY (Ruderman-Kittel-Kasuya-Yosida) interaction. For example, as shown, the magnetization directions of the first sub-pinned layer 132 and the magnetization directions of the second sub-pinned layer 136 are aligned to be antiparallel such that the total amount of magnetization of the pinned layer pattern 130 may be minimized. Since the first sub-pinned layer 132 and the second sub-pinned layer 136 constitute the pinned layer pattern 130, they may have a fixed magnetization direction.

Each of the first sub-pinned layer 132 and the second sub-pinned layer 136 may include a ferromagnetic material. For example, each of the first sub-pinned layer 132 and the second sub-pinned layer 136 may include at least one of an amorphous rare earth element alloy, multi-layer thin films in which a ferromagnetic metal (FM) and a nonmagnetic metal (NM) are alternately stacked, alloys having an L1₀ type crystal structure, cobalt-based alloys, or combinations thereof.

The anti-ferromagnetic coupling layer 134 may be interposed between the first sub-pinned layer 132 and the second sub-pinned layer 136. The first sub-pinned layer 132 and the second sub-pinned layer 136 may form an anti-ferromagnetic coupling (AFC) via the anti-ferromagnetic coupling layer 134. The anti-ferromagnetic coupling layer 134 may include a nonmagnetic material, for example, but is not limited to, at least one of ruthenium (Ru), chromium (Cr), platinum (Pt), palladium (Pd), iridium (Ir), rhodium (Rh), osmium (Os), rhenium (Re), gold (Au), copper (Cu), or combinations thereof.

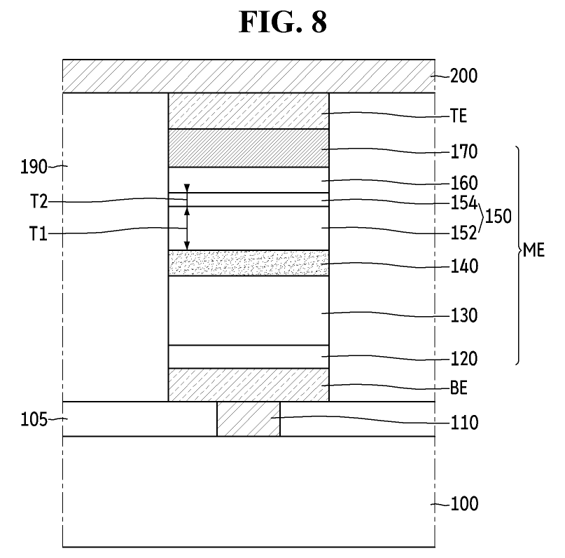

Referring to FIG. 8, the free layer pattern 150 of the magnetic memory device according to some embodiments may include a sub-free layer 152 and an insertion layer 154. That is, compared with the magnetic memory device of FIG. 3, the magnetic memory device according to FIG. 8 may not include the second sub-free layer (156 of FIG. 3). In this case, the insertion layer 154 may be interposed between the sub-free layer 152 and the oxide layer 160. The insertion layer 154 may come into contact with the oxide layer pattern 160.

The thickness T2 of the insertion layer 154 may be smaller than the thickness T1 of the sub-free layer 152. For example, the thickness T2 of the insertion layer 154 may be greater than 0 angstrom and smaller than 1.5 angstroms. Preferably, the thickness T2 of the insertion layer 154 of the magnetic tunnel junction element may be greater than 0 angstrom and smaller than 1 angstrom.

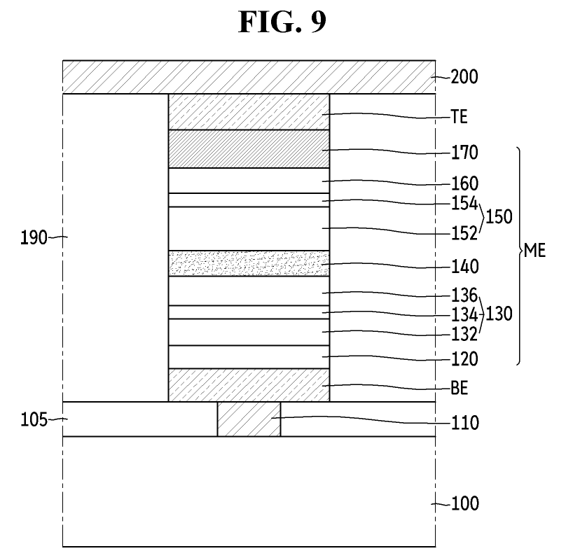

Referring to FIG. 9, in the magnetic memory device according to some embodiments, the pinned layer pattern 130 may include a synthetic antiferromagnet (SAF) compared to the pinned layer pattern 130 of FIG. 8.

For example, the pinned layer pattern 130 may include a first sub-pinned layer 132, an antiferromagnetic coupling layer 134, and a second sub-pinned layer 136 which are sequentially stacked on the seed layer pattern 120. The description of the pinned layer pattern 130 described above using FIG. 7 may be similarly applied to the pinned layer pattern 130 of FIG. 8.

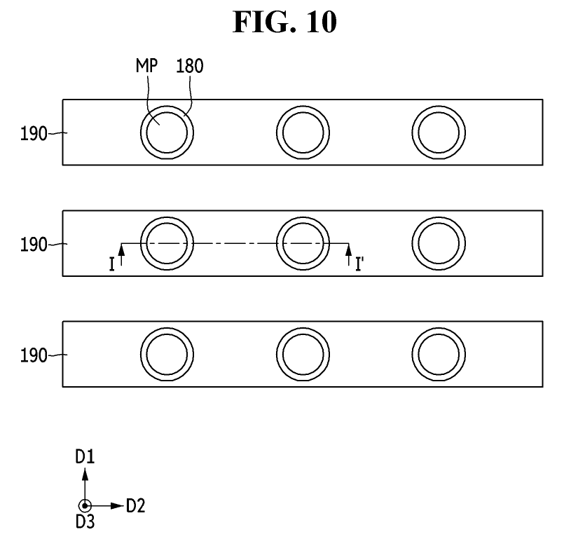

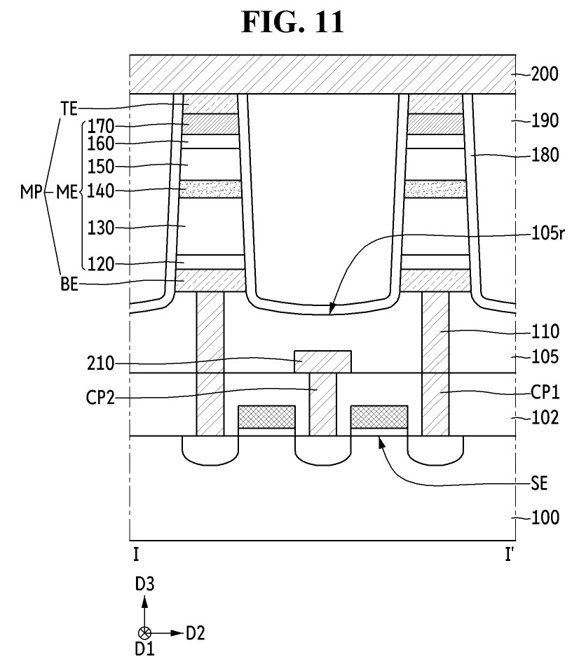

FIG. 10 is an exemplary plan view of a magnetic memory device according to some embodiments. FIG. 11 is a cross-sectional view taken along a line I-I’ of FIG. 10. For convenience of explanation, repeated parts of contents explained above using FIGS. 1 through 9 will be briefly described or omitted.

Referring to FIG. 11, the magnetic memory device according to some embodiments includes a substrate 100, a selection element SE, a source line 210, a plurality of memory cells MP, and a conductive line 200.

The substrate 100 may extend in each of a first direction D1 and a second direction D2 that intersect each other. Each of the first direction D1 and the second direction D2 may mean horizontal directions that perpendicularly intersect each other. The third direction D3 may mean a height direction perpendicular to each of the first direction D1 and the second direction D2.

The selection element SE may be formed on the substrate 100. Although the selection element SE is shown as being a MOS field effect transistor, this is only an example. As another example, a diode or a bipolar transistor may constitute the selection element SE.

The source line 210 may be formed on the substrate 100. The source line 210 may be electrically connected to the selection element SE. For example, a third interlayer insulating film 102 which covers the selection element SE may be formed on the substrate 100. The source line 210 may be formed on the third interlayer insulating film 102. Also, a source contact CP2 which penetrates the third interlayer insulating film 102 to connect the selection element SE and the source line 210 may be formed. Although only two adjacent selection elements SE are shown to share one source line 210, this is merely an example. As another example, it goes without saying that the source lines 210 corresponding to each of the selection elements SE may be provided.

A plurality of memory cells MP may be formed on the substrate 100. Each memory cell MP may be electrically connected to the selection element SE. For example, a first interlayer insulating film 105 which covers the source line 210 may be formed on the third interlayer insulating film 102. The memory cells MP may be formed on the first interlayer insulating film 105. Also, a landing contact CP1 which penetrates the third interlayer insulating film 102 may be formed, and a contact plug 110 which penetrates the first interlayer insulating film 105 to connect the landing contact CP1 and each memory cell MP may be formed.

Each memory cell MP may include a lower electrode pattern BE, a magnetic tunnel junction element ME, and an upper electrode pattern TE. The magnetic tunnel junction element ME may include at least one of the magnetic tunnel junction elements ME explained above using FIGS. 1 through 10. As an example, the magnetic tunnel junction element ME may include the seed layer pattern 120, the pinned layer pattern 130, the tunnel barrier layer pattern 140, the free layer pattern 150, the oxide layer pattern 160 and the capping layer pattern 170 explained above using FIG. 3.

In some embodiments, a capping liner 180 which covers each memory cell MP may be formed. For example, the capping liner 180 may conformally extend along the profile of the upper side of the first interlayer insulating film 105 and the profile of the side faces of each memory cell MP. The second interlayer insulating film 190 may be stacked on the capping liner 180.

The capping liner 180 may be provided as a protective layer that protects the memory cells MP from moisture or oxidation. For example, the capping liner 180 may prevent the characteristics of the magnetic tunnel junction element ME (e.g., a retention, coercivity (Hc), a resistance-area multiplication (RA), a TMR ratio (Tunneling Magnetoresistance ratio, etc.) from degrading due to moisture or oxidation. The capping liner 180 may include, for example, but is not limited to, a silicon nitride film.

In some embodiments, the upper part of the first interlayer insulating film 105 may include a recess 105r. The recess 105r may be formed inside the first interlayer insulating film 105 between the memory cells MP. The recess 105r may be formed by removing a part of the upper part of the first interlayer insulating film 105 in the process of patterning of the memory cells MP. In some embodiments, a part of the capping liner 180 may extend along the recess 105r.

The conductive line 200 may be formed on the second interlayer insulating film 190 and the memory cells MP. The conductive line 200 may be electrically connected to a plurality of memory cells MP arranged along the direction in which conductive line 200 extends. In some embodiments, the conductive line 200 may be provided as the bit line BL of FIG. 2.

A method for fabricating a magnetic memory device according to some embodiments will be described below referring to FIGS. 1 through 16.

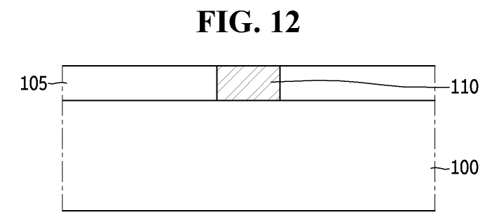

FIGS. 12 through 16 are intermediate step diagrams for describing the method for fabricating the magnetic memory device according to some embodiments. For convenience of explanation, repeated parts of contents explained above using FIGS. 1 through 11 will be briefly explained or omitted.

Referring to FIG. 12, the first interlayer insulating film 105 and the contact plug 110 are formed on the substrate 100.

For example, the first interlayer insulating film 105 may be formed on the substrate 100. Subsequently, a contact plug 110 which penetrates the first interlayer insulating film 105 and is connected to the selection element (e.g., SE of FIG. 2) on the substrate 100 may be formed.

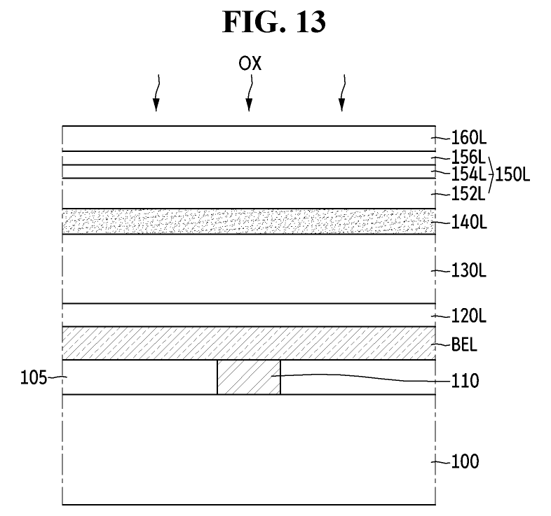

Referring to FIG. 13, a lower electrode layer BEL, a seed layer 120L, a pinned layer 130L, a tunnel barrier layer 140L and a free layer 150L are formed on the first interlayer insulating film 105 and the contact plug 110.

For example, a lower electrode layer BEL connected to the contact plug 110 may be formed on the first interlayer insulating film 105. The seed layer 120L, the pinned layer 130L, the tunnel barrier layer 140L and the free layer 150L may be sequentially stacked on the lower electrode layer BEL.

The pinned layer 130L, the tunnel barrier layer 140L and the free layer 150L may correspond to the pinned layer pattern 130, the tunnel barrier layer pattern 140 and the free layer pattern 150 explained above using FIG. 3, respectively.

Each of the pinned layer 130L, the tunnel barrier layer 140L and the free layer 150L may be formed by, but are not limited to, a physical vapor deposition (PVD) (e.g., a sputtering process), a chemical vapor deposition (CVD) process or an atomic layer deposition (ALD) process.

The free layer 150L may include boron (B). For example, the free layer 150L may include at least one of cobalt (Co), iron (Fe) and nickel (Ni), or boron (B). In some other embodiments, the free layer 150L may not include boron (B).

After that, an oxide layer 160L is formed on the free layer 150L.

For example, a preliminary oxidation layer is formed on the free layer 150L. The preliminary oxidation layer may include metal. For example, the preliminary oxidation layer may include at least one of tantalum (Ta), magnesium (Mg), iron (Fe), cobalt (Co), tungsten (W), iridium (Ir), ruthenium (Ru), molybdenum (Mo), hafnium (Hf), zirconium (Zr), niobium (Nb), aluminum (Al), manganese (Mn) or alloys thereof. Next, an oxidation process (OX) is performed on the preliminary oxidation layer. Therefore, the oxide layer 160L containing a metal oxide may be formed.

When the free layer 150L includes boron (B), the oxide layer 160L may further include boron (B). For example, the preliminary oxidation layer may include metal boride. The metal boride may include, for example, at least one of TaB, MgB, FeB, CoB, CoFeB, IrB, RuB, MoB, HfB or ZrB. As the oxidation process (OX) is performed on the preliminary oxidation layer including the metal boride, the oxide layer 160L including metal borate may be formed.

When the free layer 150L does not include boron (B), the oxide layer 160L may also include no boron (B).

The free layer 150L may include a first sub-free layer 152L, an insertion layer 154L, and a second sub-free layer 156L. Each of the first sub-free layer 152L, the insertion layer 154L, and the second sub-free layer 156L may correspond to the first sub-free layer 152, the insertion layer 154, and the second sub-free layer 156, respectively, described above using FIG. 3.

As an example, the first sub-free layer 152L includes at least one of cobalt (Co) or iron (Fe), the insertion layer 154L includes at least one of molybdenum (Mo), vanadium (V), tungsten (W), aluminum (Al) or titanium (Ti), and the second sub-free layer 156L includes iron (Fe), but may not include cobalt (Co).

A thickness of the insertion layer 154L may be thinner than a thickness of the first sub-free layer 152L.

The insertion layer 154L may include a material having a higher boron affinity than the first sub-free layer 152L. The oxide layer 160L may include a material having a higher boron affinity than the insertion layer 154L.

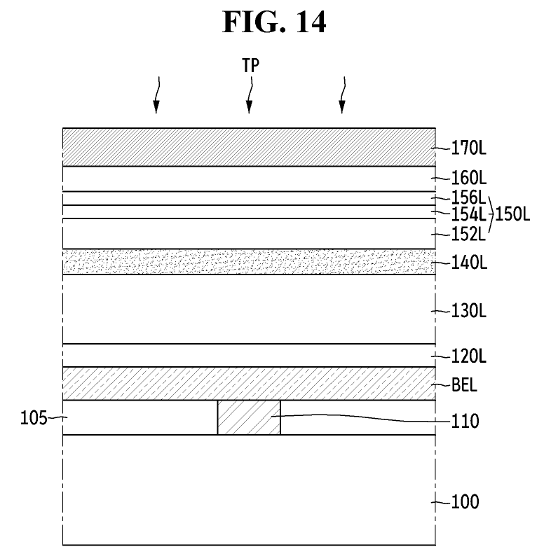

Referring to FIG. 14, a capping layer 170L is formed on the oxide layer 160L.

The capping layer 170L may include a metal or a metal nitride. The metal may be, for example, but is not limited to, at least one of tantalum (Ta), magnesium (Mg), tungsten (W), iridium (Ir), ruthenium (Ru), molybdenum (Mo), hafnium (Hf) or zirconium (Zr). The metal nitride may be, for example, but is not limited to, at least one of titanium nitride (TiN), tantalum nitride (TaN), aluminum nitride (AlN), zirconium nitride (ZrN), niobium nitride (NbN), molybdenum nitride (MoN), or combinations thereof.

When the free layer 150L includes boron (B), the capping layer 170L may further include boron (B). For example, the capping layer 170L may include a metal boride. The metal boride may include at least one of, for example, TaB, MgB, CoFeB, IrB, RuB, MoB, HfB, or ZrB.

When the free layer 150L does not include boron (B), the capping layer 170L may also not include boron (B).

After the capping layer 170L is formed, an annealing process TP may be performed. The annealing process TP may be performed at, for example, but is not limited to, 350°C to 400°C. As described above, since the free layer 150L includes the insertion layer 154L, the diffusion of boron atoms due to the annealing process TP may be minimized. Accordingly, the distribution of switching current is improved, and a method for fabricating a magnetic memory device with improved performance and reliability.

In some embodiments, as the annealing process TP is performed, oxygen atoms included in the oxide layer 160L may diffuse into the capping layer 170L. For example, a part of the capping layer 170L adjacent to the oxide layer 160L may include oxygen.

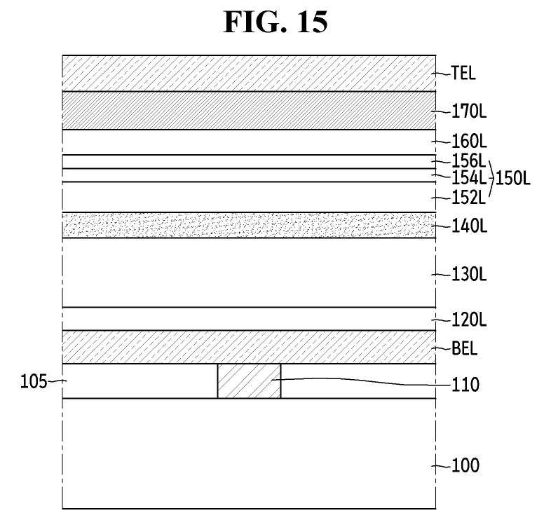

Referring to FIG. 15, an upper electrode layer TEL is formed on the capping layer 170L.

The upper electrode layer TEL may include, for example, but is not limited to, a conductive metal or a conductive metal nitride. For example, the upper electrode layer TEL may include at least one of ruthenium (Ru), tantalum (Ta), or nitrides thereof.

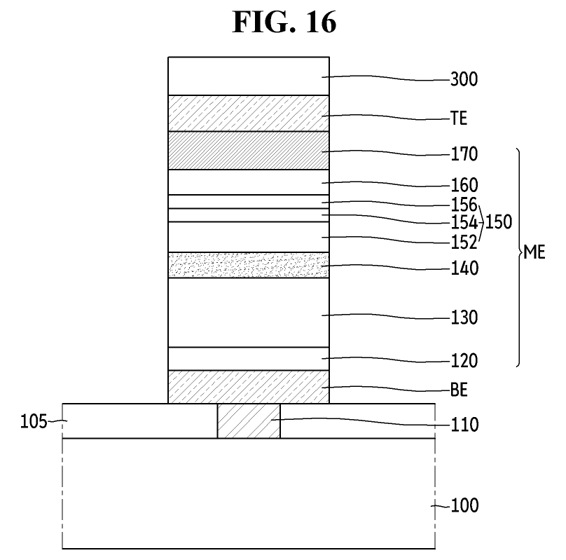

Referring to FIG. 16, a lower electrode pattern BE, a magnetic tunnel junction element ME, and an upper electrode pattern TE are formed.

For example, a mask pattern 300 may be formed on the upper electrode layer TEL of FIG. 15. Next, an etching process which uses the mask pattern 300 as an etching mask may be performed. As the etching process is performed, the lower electrode layer BEL, the seed layer 120L, the pinned layer 130L, the tunnel barrier layer 140L, the free layer 150L, the oxide layer 160L, the capping layer 170L, and the upper electrode layer TEL of FIG. 15 may be patterned. As a result, the lower electrode pattern BE, the seed layer pattern 120, the pinned layer pattern 130, the tunnel barrier layer pattern 140, the free layer pattern 150, the oxide layer pattern 160, the capping layer pattern 170 and the upper electrode pattern TE may be formed.

Next, referring to FIG. 3, a second interlayer insulating film 190 and a conductive line 200 are formed. As a result, the magnetic memory device described above using FIG. 3 may be fabricated.

Although the embodiments of the present disclosure have been described above with reference to the accompanying drawings, the present disclosure is not limited to the above embodiments, and may be fabricated in various different forms. Those skilled in the art will appreciate that the present disclosure may be embodied in other specific forms without changing the technical spirit or essential features of the present disclosure. Accordingly, the above-described embodiments should be understood in all respects as illustrative and not restrictive.

What is claimed is:

1. A magnetic memory device comprising:
a pinned layer pattern;
a free layer pattern on the pinned layer pattern;
a tunnel barrier layer pattern between the pinned layer pattern and the free layer pattern; and
an oxide layer pattern spaced apart from the tunnel barrier layer pattern with the free layer pattern interposed therebetween, the oxide layer pattern including tantalum (Ta) oxide,
wherein the free layer pattern includes a first sub-free layer and a second sub-free layer stacked in sequence,
a thickness of the second sub-free layer is smaller than that of the first sub-free layer, and
the second sub-free layer includes a material having a higher boron affinity than the first sub-free layer.

2. The magnetic memory device of claim 1,
wherein the oxide layer pattern includes a material having a higher boron affinity than the second sub-free layer.

3. The magnetic memory device of claim 1,
wherein the second sub-free layer includes a material having a higher boron affinity than the oxide layer pattern.

4. The magnetic memory device of claim 1,
wherein the free layer further includes a third sub-free layer between the second sub-free layer and the oxide layer pattern.

5. The magnetic memory device of claim 4,
wherein a thickness of the third sub-free layer is smaller than the thickness of the first sub-free layer.

6. The magnetic memory device of claim 4,
wherein the third sub-free layer includes iron (Fe).

7. The magnetic memory device of claim 1,
wherein the first sub-free layer includes at least one of cobalt (Co) or iron (Fe).

8. The magnetic memory device of claim 1,
wherein the second sub-free layer includes at least one of molybdenum (Mo), vanadium (V), tungsten (W), aluminum (Al), or titanium (Ti).

9. The magnetic memory device of claim 1,
wherein the thickness of the second sub-free layer is greater than 0 angstrom and less than 1.5 angstroms.

10. The magnetic memory device of claim 1,
wherein the pinned layer pattern includes a synthetic antiferromagnet.

11. The magnetic memory device of claim 1, further comprising:
a capping layer pattern spaced apart from the free layer pattern with the oxide layer pattern interposed therebetween; and
an upper electrode on the capping layer pattern.

12. A magnetic memory device comprising:
a pinned layer pattern;
a free layer pattern on the pinned layer pattern;
a tunnel barrier layer pattern between the pinned layer pattern and the free layer pattern;
an oxide layer pattern spaced apart from the tunnel barrier layer pattern with the free layer pattern interposed therebetween, the oxide layer pattern including a metal oxide; and
a capping layer pattern spaced apart from the free layer pattern with the oxide layer pattern interposed therebetween,
wherein the free layer pattern includes a first sub-free layer and a second sub-free layer that include different metal materials from each other and are sequentially stacked, and further an insertion layer between the first and second sub-free layers,
a thickness of the insertion layer is smaller than a thickness of the first sub-free layer,
the first sub-free layer includes cobalt iron boride (CoFeB),
the second sub-free layer is free of cobalt (Co), and
the insertion layer includes a material having a greater boron affinity than the first sub-free layer.

13. The magnetic memory device of claim 12,
wherein the oxide layer pattern includes a material having a higher boron affinity than the insertion layer.

14. The magnetic memory device of claim 12,
wherein the insertion layer includes a material having a higher boron affinity than the oxide layer pattern.

15. The magnetic memory device of claim 12,
wherein the insertion layer includes at least one of molybdenum (Mo), vanadium (V), tungsten (W), aluminum (Al) or titanium (Ti).

16. The magnetic memory device of claim 12,
wherein the oxide layer pattern includes at least one of tantalum (Ta), magnesium (Mg) or niobium (Nb).

17. The magnetic memory device of claim 12,
wherein the thickness of the insertion layer is greater than 0 angstrom and less than 1 angstrom.

18. A magnetic memory device comprising:
a lower electrode on a substrate;
an upper electrode on the lower electrode; and
a magnetic tunnel junction element between the lower electrode and the upper electrode,
wherein the magnetic tunnel junction element includes:
a seed layer on the lower electrode;
a pinned layer pattern on the seed layer;
a free layer pattern on the pinned layer pattern;
a tunnel barrier layer pattern between the pinned layer pattern and the free layer pattern;
an oxide layer pattern spaced apart from the tunnel barrier layer pattern with the free layer pattern interposed therebetween, the oxide layer pattern including tantalum (Ta) oxide; and
a capping layer pattern spaced apart from the free layer pattern with the oxide layer pattern interposed therebetween, and
wherein the free layer pattern includes a first sub-free layer and a second sub-free layer stacked in sequence, and further includes an insertion layer between the first and second sub-free layers,
the first sub-free layer includes at least one of cobalt (Co) or iron (Fe),
the second sub-free layer includes iron (Fe) and is free of cobalt (Co),
the insertion layer includes at least one of molybdenum (Mo), vanadium (V), tungsten (W), aluminum (Al) or titanium (Ti), and
a thickness of the insertion layer is smaller than a thickness of the second sub-free layer.

19. The magnetic memory device of claim 18,
wherein the insertion layer includes a material having a higher boron affinity than the first sub-free layer and a lower boron affinity than the oxide layer pattern.

20. The magnetic memory device of claim 18,
wherein a thickness of the insertion layer that is greater than 0 angstrom and less than 1 angstrom.
